(19) United States
(12) Patent Application Publication
(10) Pub. No.: US 2010/0244903 A1
(43) Pub. Date: Sep. 30, 2010

(54) TUNEABLE FILTER

(75) Inventors: Nicholas John Easton, Chelmsford (GB); Christopher Ralph Pescod, Chelmsford (GB); Richard Peter Joyce, Chelmsford (GB)

Correspondence Address: KENYON & KENYON LLP, ONE BROADWAY, NEW YORK, NY, 10004, US

(73) Assignee: BAE SYSTEMS plc, London (GB)

(21) Appl. No.: 12/304,110

(22) PCT Filed: Nov. 14, 2008
(86) PCT No.: PCT/GB2008/051062

§ 371 Date: Jun. 15, 2010

(30) Foreign Application Priority Data
Nov. 28, 2007 (EP) 07254600.5
Nov. 28, 2007 (GB) 0723294.5

(51) Int. Cl. H03B 21/00; H03H 7/01

(52) U.S. Cl. 327/105; 333/176; 327/156

(57) ABSTRACT

A tuneable filter is provided in which a received signal in a first frequency range is translated to a signal of a higher frequency range by a switchable frequency oscillator signal, filtered in a narrow band filter and then down-converted, possibly to the first frequency range. The switchable frequency oscillator signals are generated by a synthesizer which operates by mixing oscillator signals of different frequencies, selected by fast-switching microwave switches, in order to generate the required range of oscillator signal frequencies.

### RELATED APPLICATION INFORMATION

This application is a United States National Phase Patent Application of International Patent Application No. PCT/GB2008/051062 which was filed on Nov. 14, 2008, and claims priority to British Patent Application No. 0723294.5, filed on Nov. 28, 2007, and claims priority to European Patent Application No. 07254600.5, filed on Nov. 28, 2007, the disclosures of each of which are incorporated herein by reference.

### FIELD OF THE INVENTION

The present invention relates to tuneable filters and in particular, but not exclusively, to a fast-tuning band-pass filter and associated synthesizer.

### BACKGROUND INFORMATION

It has been found that known tuneable filter designs suffer from limited performance against at least one of a number of key requirements that relate to tuning speed, operational frequency range, size and cost. Furthermore, known tuneable filters are prone to intermodulation distortion effects which may be significant in certain applications.

### SUMMARY OF THE INVENTION

From a first aspect, the present invention resides in a tuneable filter, including:

an input for receiving a signal in a first frequency range;

a first mixer, arranged to combine a first oscillator signal with a signal received at said input to thereby translate the received signal to a signal in a second frequency range;

a filter, arranged to pass signals of frequencies within a predetermined frequency band within said second frequency range; and

a second mixer, arranged to combine a second oscillator signal with a signal passed by said filter to thereby translate said filtered signal to a signal in a third frequency range, different to said second frequency range.

In an exemplary embodiment, the tuneable filter further includes a synthesizer operable to generate the first oscillator signal and to switchably select the frequency of the first oscillator signal from a plurality of predetermined frequencies. These predetermined frequencies and the number of available frequencies are selected to enable the tuneable filter to select signals of a required bandwidth from any portion of the first frequency range.

In a further exemplary embodiment, the synthesizer is further operable to generate the second oscillator signal and to switchably select the frequency of the second oscillator signal from the same plurality of predetermined frequencies. In certain applications, the option remains to output the selected signals in any frequency range, not necessarily the same as the first frequency range, according to the frequency of the second oscillator signal.

In an exemplary mode of operation, the synthesizer is arranged to generate both the first and said second oscillator signals at the same frequency, and the third frequency range is the same as the first frequency range. That is, having selected signals in a required portion of the first frequency range, the tuneable filter outputs the selected signals at the same frequency as they were input.

Alternatively, a fixed frequency oscillator may be used to generate the second oscillator signal so that all signals output by the tuneable filter are in the same frequency range.

The filter may be a fixed band-pass filter for the predetermined frequency band. However, a simple tuneable band-pass filter may be used alternatively to enable a reduction in the number of different oscillator signal frequencies that need to be generated by the synthesizer in order for the tuneable filter to select signals from the first frequency range to the resolution required.

The synthesizer may include a plurality of oscillators and an arrangement for combining signals output from selected ones of the plurality of oscillators to thereby generate oscillator signals of the plurality of predetermined frequencies. To ensure phase coherence of generated oscillator signals at any one of the predetermined frequencies, the synthesizer further includes a single crystal reference for the plurality of oscillators.

According to this first aspect of the present invention, in its simplest form and in an exemplary embodiment of the present invention, a tuneable filter has been implemented using an up-converter to translate a signal in an input frequency range to a higher frequency range, a fixed filter for selecting signals in a predetermined frequency band from within that higher frequency range, and a down-converter for translating the selected signals back to a signal in the input frequency range. The up and down-converters are supplied with an oscillator signal of a range of discrete frequencies by a fast-switching synthesizer. The fast-switching capability of the synthesizer provides for a correspondingly fast-tuning tuneable filter and hence rapid selection of signals from within the input frequency range.

In a typical application, an input signal in the 6-18 GHz frequency range is up-converted and then fed through a fixed filter with a 1 GHz wide band. That part of the input frequency range that is required to be passed by the filter is selected by setting the synthesizer to output an oscillator signal of an appropriate frequency for combining with the input signal in the up-converter. The frequency of the synthesizer output signal may be adjusted in 1 GHz steps so that signals in the required part of the input frequency range may be selected in 1 GHz steps.

Exemplary embodiments of this first aspect of the present invention provide for the development of a low cost, compact, fast-tuning, combined band-pass filter, synthesizer and down-converter, all within a single compact circuit, suitable for use with a Digital Radio Frequency (RF) Memory (DRFM). In such applications, the tuneable filter is required to define the input band that will subsequently be sampled and/or synthesised, possibly with very rapid switching between required portions of the input band.

By using a single crystal reference for all the oscillators and using microwave switches, the tuneable filter in exemplary embodiments of the present invention can be switched and returned as necessary within a required settling time. The use of fixed filters enables the filtering requirements to readily be met, and power handling, gain, noise figure and dynamic range requirements can readily be achieved.

The particular architecture of the tuneable filter and synthesizer apparatus of the present invention enables compact COTS components and high density packaging to be used to fabricate a combined tuneable filter and synthesizer.

From a second aspect, the present invention resides in a signal processing apparatus, including:

an input for receiving signals in a first frequency range;

a tuneable filter according to the first aspect of the present invention for switchably selecting signals of a predetermined bandwidth from signals received at the input;

a first frequency translation arrangement for translating signals selected by the tuneable filter into signals of a frequency for processing; and

a processing arrangement for processing the selected signals.

In an exemplary embodiment, the signal processing apparatus further includes a second frequency translation arrangement for translating processed signals into signals in the first frequency range.

To ensure immunity from the effects of frequency mismatches between the first and second frequency translation arrangements, the first and second frequency translation arrangements are arranged to receive oscillator signals of a given frequency from a common oscillator signal source.

In an exemplary application, the processing arrangement includes an analogue to digital (A-D) converter and a DRFM. The processed signals are returned to the analogue domain and then passed through a sequence of up-conversion and down-conversion stages in the second frequency translation arrangement, each corresponding to a down-conversion and up-conversion stage respectively that were implemented by the tuneable filter and the first frequency translation arrangement, to create an output signal in the same first frequency range as the original input signal.

Corresponding conversion stages may use the same respective oscillator signals, for example those output by the same respective fast-switching synthesizers, so ensuring phase coherence between oscillator signals of the same frequency. This, combined with the use of fixed filters, has the particular advantage in providing substantial immunity between corresponding conversion stages to oscillator frequency drift and phase variations that might otherwise exist between different oscillator sources. This has the advantage that the processed input signals carry no effects beyond those imparted by the processing arrangement, for example the DRFM.

In an exemplary embodiment, the fast-switching synthesizers are implemented using a switchable network of fixed high and low frequency oscillators whose signals may be mixed to synthesise the required frequencies for supplying the conversion stages, in the tuneable filter in particular. All the fast-switching synthesizers may be phase locked so that no unwanted effects due to phase mismatches are introduced into the processed signals.

### BRIEF DESCRIPTION OF THE DRAWINGS

FIG. 1 is a diagram showing the principal components of a tuneable filter according to an exemplary embodiment of the present invention.

FIG. 2 is a diagram showing the principal components of a signal processor according to a further exemplary embodiment of the present invention incorporating the tuneable filter of FIG. 1.

FIG. 3 is a diagram showing the principal components of exemplary signal processing apparatus for use in electronic warfare systems.

FIG. 4 is a diagram showing the principal components of an exemplary switchable frequency synthesizer for use as the first local oscillator signal source (LO1) in the signal processing apparatus shown in FIG. 3.

FIG. 5 is a diagram showing an exemplary oscillator for use as the second local oscillator source (LO2) in the signal processing apparatus shown in FIG. 3.

FIG. 6 is a diagram showing the principal components of an exemplary switchable frequency synthesizer for use as the third local oscillator signal source (LO3) in the signal processing apparatus shown in FIG. 3.

### DETAILED DESCRIPTION

Exemplary embodiments of the present invention will now be described in more detail, by way of example only, with reference to the accompanying drawings.

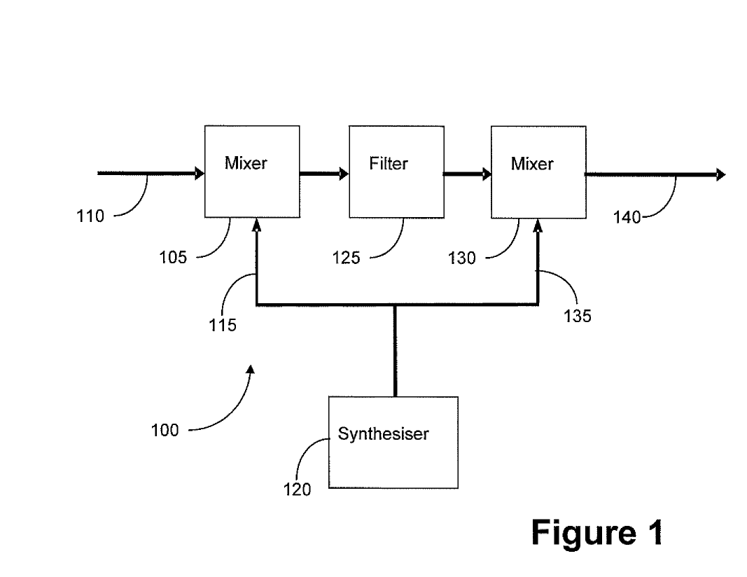

A tuneable filter according to a first embodiment of the present invention will now be described with reference to FIG. 1.

Referring to FIG. 1, the tuneable filter 100 is shown to include a first mixer 105 arranged to receive, at a first input 110, an input signal within a first frequency range and to mix the input signal with a first oscillator signal received at a second input 115 to the mixer 105 so as to up-convert the input signal to a signal in a second, higher frequency range. The first oscillator signal is generated by a synthesizer 120. The up-converted signal is passed through a narrow band fixed filter 125 and the filtered signal is then combined with a second oscillator signal (135) in a second mixer 130 to down-convert the filtered signal to a third frequency range. The second oscillator signal (135) may be generated by the same synthesizer 120. The filtered and down-converted signal is output from the tuneable filter 100 at an output 140.

The filtered signal may be down-converted by the second mixer 130 to the first frequency range by combining it with a second oscillator signal having the same frequency as the first oscillator signal. This has the effect of selecting a portion of the first frequency range, as determined by the frequency of the first oscillator signal (115) and the frequency range passed by the narrow band fixed filter 125. The first (115) and second (135) oscillator signals may be one and the same oscillator signal, as generated by the synthesizer 120. One advantage of supplying the same oscillator signal to both mixers 105, 130 from the one synthesizer 120 is that there are no detectable effects on the filtered signal due to drift in the frequency and/or phase of the synthesizer output between the up-conversion and down-conversion stages. Another advantage is a cost saving over the alternative of providing two separate oscillators.

The tuneable filter 100 may be tuned to select signals in different portions of the first frequency range by varying the frequency of the oscillator signal output by the synthesizer 120. The synthesizer 120 may be arranged to switch the oscillator signal frequency in predetermined steps over a predetermined range of frequencies. This enables signals in different portions of the first frequency range to be selected and output by the tuneable filter 100 in corresponding steps. Furthermore, the synthesizer 120 may be designed, according to an exemplary embodiment of the present invention to be described below, to switch very rapidly between the different predetermined oscillator frequencies to enable different portions of the first frequency range to be selected very rapidly.

By way of example, consider a tuneable filter 100 that is required to select signals in different 1 GHz bands from input signals in a first frequency range of 6-18 GHz. There are numerous choices for a center frequency of a 1 GHz bandwidth fixed bandpass filter 125 and for the oscillator signal frequency that will achieve this objective. In one example, this can be achieved using a 1 GHz bandwidth narrow band filter 125 having a center frequency of 32.5 GHz and a synthesizer 120 arranged to output switchable oscillator signals in the frequency range 26-14 GHz in 1 GHz steps. For example, if the synthesizer 120 is set to output an oscillator signal of frequency 26 GHz, then the input first frequency range is up-converted in the first mixer 105 to a second frequency range of 32-44 GHz. The filter 125 then restricts this to 32-33 GHz—the first 1 GHz band in that range—which corresponds to the first 1 GHz band—the 6-7 GHz band—of the input first frequency range. This 32-33 GHz filtered signal is then mixed with the same 26 GHz oscillator signal from the synthesizer 120 in the second mixer 130 to down-convert it to a signal in the 6-7 GHz band. Similarly, setting the oscillator signal to 25 GHz will select the 7-8 GHz band from the input signal, and so on. Thus, if the synthesizer 120 is arranged to output oscillator signals decreasing in frequency in 1 GHz steps, the output signal will be in 1 GHz bands with a center increasing in 1 GHz steps.

The tuneable filter 100 may be applied to filtering of other frequency bands, for example to the wider 2-18 GHz band, by selecting a synthesizer 120 with a suitable switchable oscillator frequency range.

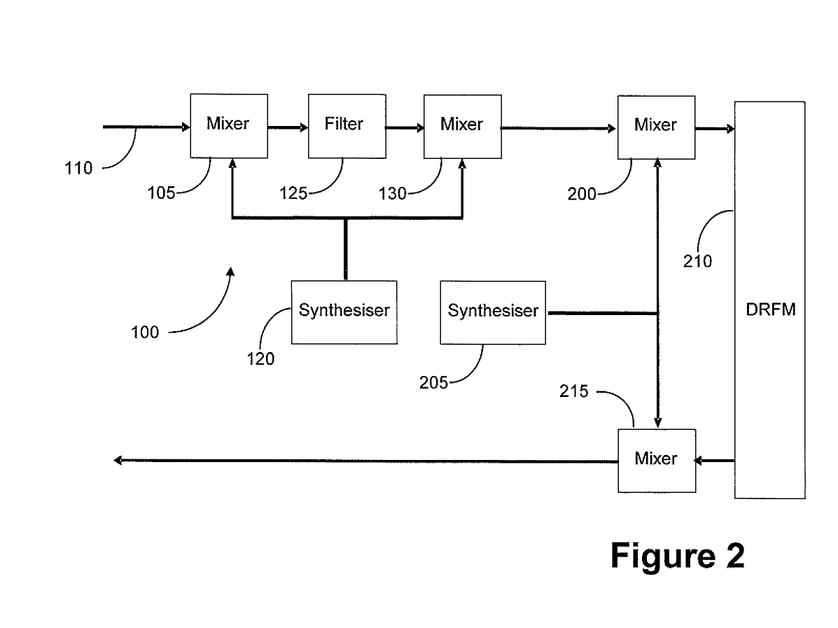

According to a second embodiment of the present invention, the tuneable filter 100 may be applied to a signal processing apparatus based upon a digital radio frequency memory (DRFM), as will now be described with reference to FIG. 2.

Referring to FIG. 2, a tuneable filter 100 according to the first embodiment described above is provided to receive at an input 110 an input signal within a first frequency range and to output signals in selected filtered bands from that first frequency range. The signals output by the tuneable filter 100, possibly in the first frequency range, are translated to a baseband or other appropriate intermediate frequency range by a third mixer 200 arranged to combine the output signals with an oscillator signal at an appropriate frequency output by a second synthesizer 205. The translated output signal of the third mixer 200 is then input to a DRFM 210 where digitisation and further signal processing may be performed. Following processing within the DRFM 210, the processed signal may be translated back into the first frequency range using a fourth mixer 215 in which the same oscillator signal output from the second synthesizer 205 is mixed with the processed signal. By using the same synthesizer 205 to generate the oscillator signals used for frequency translation in the third and fourth mixers 200, 215, the advantage mentioned above is maintained of imparting no detectable effects on the processed signal due to frequency drift or phase mismatch in the output of the synthesizer 205 between the pre- and post-processing conversion stages. This is of particular importance where the act of processing the signal by the DRFM 210 is intended to be substantially undetectable. This objective may be undermined in prior art systems by detectable characteristics introduced into the processed signal, for example as a result of frequency mismatches between corresponding frequency conversion stages. Performance shortfalls of this type are substantially avoided in exemplary embodiments of the present invention.

To continue with the example described above in which selectable 1 GHz wide bands of an input signal in the 6-18 GHz frequency band are output by the tuneable filter 100: the third mixer 200 in combination with the second synthesizer 205 may be arranged to translate each of the output 1 GHz bands to signals in the frequency range 0-1 GHz, suitable for digitisation and processing by the DRFM 210. The same oscillator signal from the second synthesizer 205 may then be used to up-convert the processed output of the DRFM 210 to the respective 1 GHz portion of the first frequency range of 6-18 GHz selected by the tuneable filter 100. This may be achieved if the second synthesizer 205 is arranged to provide switchable frequency oscillator signals to the third and fourth mixers 200, 215 in the frequency range 6-18 GHz in 1 GHz steps.

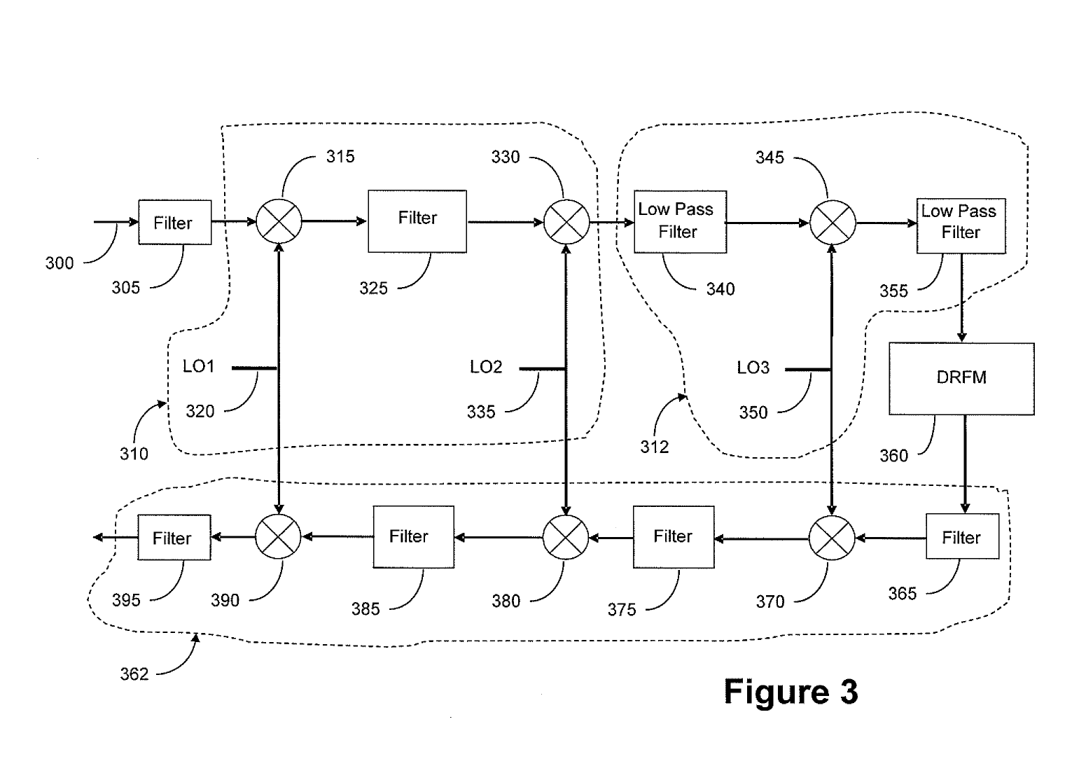

A signal processing apparatus according to a third embodiment of the present invention will now be described with reference to FIG. 3. The signal processing apparatus of this third embodiment enables a compromise to be achieved in the number of different frequencies of oscillator signal that would need to be generated by synthesizers in the apparatus while still enabling the apparatus to operate in respect of the same 6-18 GHz first signal frequency range and to convert an input signal into baseband signals suitable for digitisation and processing by a DRFM. To continue with the example used in the first and second embodiments above, operation of the signal processing apparatus in this third embodiment will be described in the context of input signals in a first frequency range of 6-18 GHz. The objective, in this example, is to be able to rapidly select signals from the first frequency range in 2 GHz wide bands and 1 GHz steps, then to down-convert each selected 2 GHz wide band signal from the input signal into a number of selectable baseband frequency signals in the range 0-1 GHz with input center frequencies differing by 100 MHz steps. Following digital processing, the objective is to be able to up-convert the processed baseband signals to their respective frequencies within the first frequency range. It will be clear that the design of the apparatus in this third embodiment of the present invention may be altered to operate with signals in different frequency ranges to those described in this example, without significantly altering the architecture of the apparatus shown in FIG. 3.

Referring to FIG. 3, an input signal in a first frequency range, 6-18 GHz in this example, received at an input 300 to the apparatus, is passed through an initial (6-18 GHz) filtering stage 305. The initially filtered signal is then input to a tuneable filter 310 designed, as in the case of the tuneable filter 100 described above, to allow the passage of signals from any selected one of a number of predetermined frequency bands within the first frequency range. The tuneable filter 310 receives the 6-18 GHz filtered signal from the initial filtering stage 305 and up-converts it, in a first mixer 315, to a second frequency range, in this example the frequency band 26-48 GHz. The up-conversion is achieved by mixing the initially filtered 6-18 GHz signal with a first oscillator signal LO1 received at the first oscillator input 320. The first oscillator signal LO1 is switchable in 1 GHz steps between 20 GHz and 30 GHz. The up-converted signal is passed through a narrow band filter 325, in this example a fixed band-pass filter having a center frequency of 37 GHz and a 2 GHz bandwidth. The narrow band filter 325 in combination with the switchable first oscillator signal LO1 enables the 6-18 GHz band to be sampled in 2 GHz wide bands each having a center frequency separated by 1 GHz.

The signal passed by the narrow band filter 325, in the frequency range 36-38 GHz, is then down-converted in a second mixer 330 by combining it with a second oscillator signal LO2, received at a second oscillator input 335. In this example, the second oscillator signal LO2 is of a fixed frequency of 34 GHz and has the effect of down-converting the 36-38 GHz signal to a third frequency range of 2-4 GHz. This is the signal output by the tuneable filter 310.

A selected 2-4 GHz signal output by the tuneable filter 310 is input to a down-converter 312. The objective to be achieved by the down-converter 312 is to translate a 1 GHz wide signal lying within the 2-4 GHz range into a baseband frequency signal in the range 0-1 GHz suitable for digital processing. The received 2-4 GHz signal is firstly passed through a low pass filter 340 and then to a down-conversion stage provided by a third mixer 345 in which the received 2-4 GHz signal is mixed with a third oscillator signal LO3 received at a third oscillator input 350. In this example, the third oscillator signal may be switchable in frequency in 0.1 GHz steps between 2 and 3 GHz. Such an oscillator frequency range is used by the third mixer 345 to translate signals in the 2-4 GHz range into signals within a fourth, baseband, frequency range of 0-1 GHz. These selectable baseband signals, after filtering in a low pass filter 355 to reject mixing products of frequencies above 1 GHz, form the output of the down-converter 312. These selectable baseband signals are then made available for digitisation and processing in a DRFM 360.

Following processing by the DRFM 360, the apparatus of this third embodiment of the present invention is provided with an up-converter 362 designed to restore a processed signal output by the DRFM 360 into a signal within the originally selected 2 GHz wide band of the first frequency range of 6-18 GHz. This post-processing frequency translation is achieved in the up-converter 362 by a series of conversion and filtering stages substantially corresponding to the pre-processing filtering and down-conversion stages, as will now be described.

The up-converter 362 firstly receives the processed signal from the DRFM 360, filters it in an initial filtering stage 365, and then inputs the processed signal to a mixer 370 to be up-converted to the third frequency range of 2-4 GHz by mixing the processed signal with the third oscillator signal LO3 set to the same frequency as used for this signal in the corresponding down-conversion stage (345) of the down-converter 312. The up-converted 2-4 GHz signal is then filtered in a filter 375 before a further up-conversion stage including a mixer 380 and the fixed second oscillator signal LO2, corresponding to the down-conversion stage 330 in the tuneable filter 310, translates the signal to the second frequency range of 36-38 GHz. A further filter 385 filters the signal before a down-conversion stage including a mixer 390 and the first oscillator signal LO1, corresponding to the down-conversion stage 315 in the tuneable filter 310, translates the signal to a frequency band within the first frequency range of 6-18 GHz, according to the frequency of the first oscillator signal LO1, and filters the down-converted signal in a filter 395 for output by the up-converter 362.

The sources of the three oscillator signals LO1, LO2 and LO3 are designed to generate oscillator signals of the same frequencies and in the same phase for use in the down-conversion and the respectively corresponding up-conversion stages. This provides substantial immunity to any effects arising from oscillator frequency drift and phase differences that would otherwise leave their mark beyond those effects intended by the DRFM 360 if different oscillators were used. In exemplary embodiments of the present invention, the switchable frequency oscillator signals are generated by synthesizers as will now be described in turn according to further exemplary embodiments of the present invention.

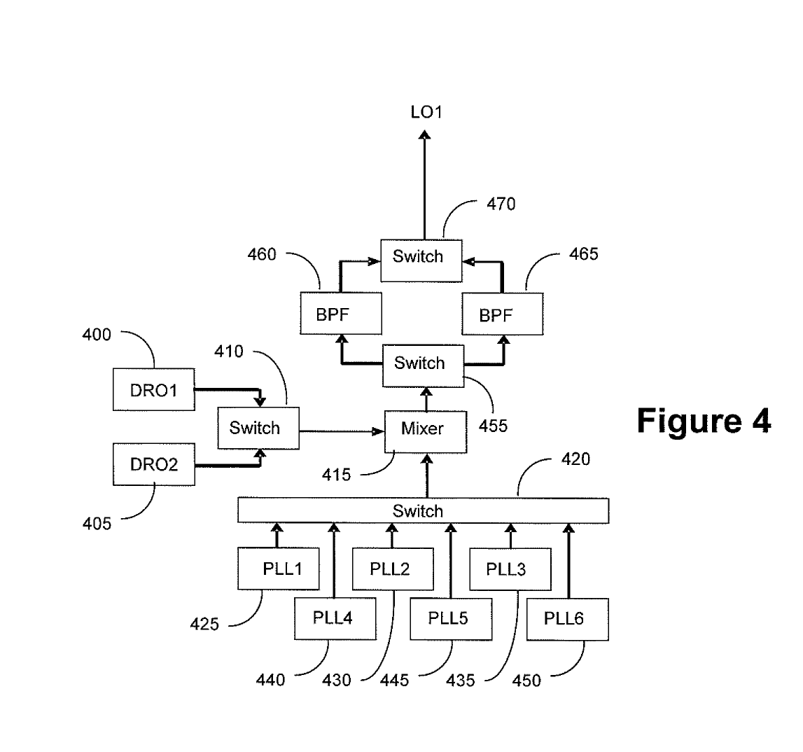

An exemplary first synthesizer for use in supplying the first local oscillator signal LO1 in the apparatus according to the third embodiment of the present invention will now be described with reference to FIG. 4. The principles of operation of this first synthesizer will be described in the context of the example frequencies used above, that is, to generate switchable oscillator signals in the frequency range 20-30 GHz in 1 GHz steps.

Referring to FIG. 4, in the exemplary first synthesizer, oscillator signals output from a first dielectric resonator oscillator (DRO) DRO1 400 and a second DRO (DRO2) 405 are selectable by a microwave switch 410. The first DRO 400 is arranged to generate an oscillator signal at a frequency of 22 GHz and the second DRO 405 at a frequency of 17 GHz. The selected DRO oscillator signal is passed as one input to a mixer 415.

The oscillator signals generated by each in a bank of six phase locked loop (PLL) oscillators PLL1 to PLL6, reference numerals 425 to 450 in FIG. 4, are individually selectable by a microwave switch 420. In this example, the six PLL oscillators 425-450 generate oscillator signals at frequencies of 3, 4, 5, 6, 7 and 8 GHz respectively. The particular PLL oscillator signal selected by the switch 420 provides a second input to the mixer 415.

The oscillator signals received from the microwave switches 410 and 420 are combined in the mixer 415 and the mixed signal products are supplied to a microwave switch 455 which is arranged to direct the mixed signal to either one of two band-pass filters, 460 and 465. A further microwave switch 470 selects which one of the two band-pass filters 460, 465 will provide the oscillator signal that will form the output LO1. The band-pass filter 460 is arranged to pass the mixed signal products in the frequency range 20-25 GHz while the band-pass filter 465 is arranged to pass mixed signal products in the frequency range 26-30 GHz. By selecting appropriate combinations of switching positions for the microwave switches 410, 420, 455 and 470, the exemplary first synthesizer is operable to generate oscillator signals at frequencies between 20 and 30 GHz in 1 GHz steps. Moreover, if the DRO and PLL oscillators are arranged to operate continuously, then the microwave switches 410, 420, 455 and 470 may select between different ones of the required oscillator frequencies very rapidly, at speeds limited only by the switching speeds of the microwave switches. When coupled to a tuneable filter according to exemplary embodiments of the present invention, this first synthesizer enables very rapid tuning of the filter and hence very rapid sampling of the input frequency range. This feature is particularly advantageous in DRFM applications.

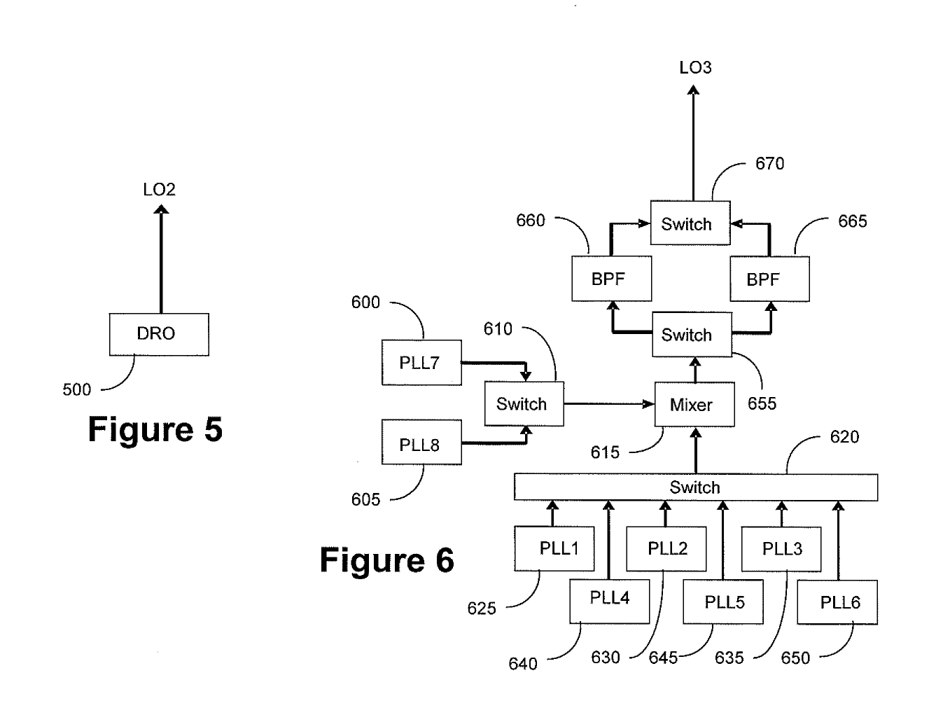

Referring to FIG. 5, the second oscillator signal LO2 may be supplied to the tuneable filter 310 by a single DRO 500, arranged in this example to generate an oscillator signal at a frequency of 34 GHz.

An exemplary second synthesizer for use in supplying the third oscillator signal LO3 in the down-converter 312 of the improved apparatus according to the third embodiment of the present invention will now be described with reference to FIG. 6. The architecture and the principles of operation of this second synthesizer are substantially identical with those for the first synthesizer described above and will not be described to the same level of detail as for the first synthesizer. The only significant difference lies in the use of PLL oscillators in place of the DROs 400, 405 of the first synthesizer, due in part to the lower frequencies being generated. In the context of the example frequencies used above, the second synthesizer is designed to generate switchable oscillator signals in the frequency range 2.0-3.0 GHz in 0.1 GHz steps.

Referring to FIG. 6, a bank of six PLL oscillators PLL1 to PLL6, referenced with numerals 625 to 650, corresponding to PLL oscillators 425 to 450 in FIG. 4, are arranged to generate oscillator signals at frequencies of 100, 200, 300, 400, 500, 600, 700 and 800 MHz respectively. Any one of these PLL oscillator signals is selectable by a switch 620. Further PLL oscillators (PLL 7) 600 and (PLL8) 605, corresponding to DROs 400, 405 of FIG. 4, are arranged to generate oscillator signals at frequencies of 3.4 GHz and 1.7 GHz respectively. Either one of these further PLL oscillator signals is selectable by a microwave switch 610. The oscillator signals selected by the switches 610 and 620 are mixed in a mixer 615 and then filtered by one of two band-pass filters 660, 665 as selected by microwave switches 655 and 670. The band-pass filter 660 is arranged to pass signals in the frequency range 2.6 to 3.0 GHz while the filter 665 is arranged to pass signals in the frequency range 2.0 to 2.5 GHz. The output of the microwave switch 670 forms the output of the exemplary second synthesizer, the switchable oscillator signal LO3.

A single crystal reference may be used to phase-lock all the oscillators in the first or the second synthesizer or to phase-lock all the oscillators in both the first and second synthesizers and the single DRO 500, and to enable the oscillator signals supplied to the tuneable filter 310, to the down-converter 312 and the post-processing up-conversion stages of the up-converter 362 to be switched and returned as necessary to the same frequencies within a required minimum settling time.

Optionally, in order to reduce the number of synthesizer frequencies required, more than one tuneable filter may be provided in the pre-processing filtering and down-conversion path, 300-355, in the apparatus of FIG. 3. A further option to provide flexibility without increasing the demands on the first synthesizer would be to use a tuneable filter in place of the fixed filter 325 in the tuneable filter 310. Only one such tuneable filter would be needed having only a small percentage tuneable bandwidth. However, there are clearly a number of alternative architectures that would be apparent to a person of ordinary skill in this field of technology that fall within the scope of the present invention and the optimum one would in practice be chosen to suit a particular application.

The use of MEMS, HTS and MMIC fabrication techniques enables a highly compact, light-weight tuneable filter and DRFM apparatus according to exemplary embodiments of the present invention to be fabricated having relatively low power consumption and at relatively low cost.

1-15. (canceled)

16. A tuneable filter, comprising:
an input for receiving a signal in a first frequency range;
a first mixer to combine a first oscillator signal with a signal received at said input to thereby translate the received signal to a signal in a second frequency range;
a filter to pass signals of frequencies within a predetermined frequency band within said second frequency range; and
a second mixer to combine a second oscillator signal with a signal passed by said filter to translate said filtered signal to a signal in a third frequency range, different than said second frequency range.

17. The tuneable filter according to claim 16, further comprising:
a synthesizer configured to generate said first oscillator signal and to select switchably the frequency of said first oscillator signal from a plurality of predetermined frequencies.

18. The tuneable filter according to claim 17, wherein said synthesizer is configured to generate said second oscillator signal and to select switchably the frequency of said second oscillator signal from said plurality of predetermined frequencies.

19. The tuneable filter according to claim 18, wherein said synthesizer is configured to generate said first and said second oscillator signals at the same frequency, and wherein said third frequency range is the same as said first frequency range.

20. The tuneable filter according to claim 17, further comprising:
a fixed frequency oscillator for generating said second oscillator signal.

21. The tuneable filter according to claim 16, wherein said filter is a fixed bandpass filter for said predetermined frequency band.

22. The tuneable filter according to claim 16, wherein said filter is a tuneable band-pass filter.

23. The tuneable filter according to claim 16, wherein said synthesizer includes a plurality of oscillators and a combining arrangement to combine signals output from selected ones of said plurality of oscillators so as to generate oscillator signals of said plurality of predetermined frequencies.

24. The tuneable filter according to claim 23, wherein said synthesizer includes a single crystal reference for said plurality of oscillators, so as to generate oscillator signals with phase coherence at any one of said predetermined frequencies.

25. The tuneable filter according to claim 23, wherein said plurality of oscillators includes at least one phase-locked loop oscillator.

26. A signal processing apparatus, comprising:
an input for receiving signals in a first frequency range;
a tuneable filter to select switchably the signals of a predetermined bandwidth from signals received at said input, the filter including:
an input for receiving a signal in a first frequency range,
a first mixer to combine a first oscillator signal with a signal received at said input to thereby translate the received signal to a signal in a second frequency range,
a filter to pass signals of frequencies within a predetermined frequency band within said second frequency range, and
a second mixer to combine a second oscillator signal with a signal passed by said filter to translate said filtered signal to a signal in a third frequency range, different than said second frequency range;
a first frequency translation arrangement for translating signals selected by said tuneable filter into signals of a frequency for processing; and
a processing arrangement to process the selected signals.

27. The signal processing apparatus according to claim 26, further comprising:
a second frequency translation arrangement to translate processed signals into signals in said first frequency range.

28. The signal processing apparatus according to claim 27, wherein the tuneable filter and the first frequency translation arrangement and the second frequency translation arrangement are configured to receive oscillator signals of a given frequency from a common oscillator signal source.
